(19) United States
(12) Patent Application Publication
(10) Pub. No.: US 2025/0248057 A1
(43) Pub. Date: Jul. 31, 2025

(54) METHOD OF MANUFACTURING SEMICONDUCTOR DEVICE AND SEMICONDUCTOR DEVICE

(71) Applicant: Tokyo Electron Limited, Tokyo (JP)

(72) Inventors: Masahiro IKEJIRI, Nirasaki City (JP); Koji AKIYAMA, Nirasaki City (JP); Naonori FUJIWARA, Nirasaki City (JP); Kazuyoshi YAMAZAKI, Nirasaki City (JP)

(21) Appl. No.: 19/087,645

(22) Filed: Mar. 24, 2025

Related U.S. Application Data
(63) Continuation of application No. PCT/JP2023/033862, filed on Sep. 19, 2023.

(30) Foreign Application Priority Data
Sep. 30, 2022 (JP) 2022-157633

(51) Int. Cl. H10D 1/68; H10B 12/00; H10D 1/00

(52) U.S. Cl. CPC H10D 1/692; H10B 12/03; H10B 12/30; H10D 1/041

(57) ABSTRACT

A method of manufacturing a semiconductor device includes: forming a lower electrode on a substrate; forming, on the lower electrode, a high dielectric constant film made of an oxide containing a tetravalent metal cation; forming, on the high dielectric constant film, an oxide film made of an oxide containing a pentavalent metal cation; forming a mixed layer having conductivity, in which the oxide containing the tetravalent metal cation and the oxide containing the pentavalent metal cation are mixed, by causing the high dielectric constant film to react with the oxide film; and forming an upper electrode.

### CROSS-REFERENCE TO RELATED APPLICATION

This application is a Bypass Continuation Application of PCT International Application No. PCT/JP2023/033862, filed on Sep. 19, 2023 and designating the United States, the international application being based upon and claiming the benefit of priority from Japanese Patent Application No. 2022-157633, filed on Sep. 30, 2022, the entire contents of which are incorporated herein by reference.

### TECHNICAL FIELD

The present disclosure relates to a method of manufacturing a semiconductor device and a semiconductor device.

### BACKGROUND

As a capacitor used for a DRAM and the like, a capacitor in which a lower electrode, a high dielectric constant film, and an upper electrode are sequentially formed on a substrate is used, and in Patent Document 1, a capacitor in which zirconium oxide is used as the high dielectric constant film is described.

Further, in Patent Document 2, it is described that a first dielectric film contains tantalum oxide or niobium oxide, a second dielectric film is provided between a lower electrode and a first dielectric film, and a third dielectric film is provided between the first dielectric film and an upper electrode. Further, it is described that zirconium oxide or the like is used for the second dielectric film and the third dielectric film.

### PRIOR ART DOCUMENTS

### Patent Documents

Patent Document 1: Japanese Patent Laid-open Publication No. 2001-152339
Patent Document 2: Japanese Patent Laid-open Publication No. 2004-266009

### SUMMARY

According to an embodiment of the present disclosure, there is provided a method of manufacturing a semiconductor device including: forming a lower electrode on a substrate; forming, on the lower electrode, a high dielectric constant film made of an oxide containing a tetravalent metal cation; forming, on the high dielectric constant film, an oxide film made of an oxide containing a pentavalent metal cation; forming a mixed layer having conductivity, in which the oxide containing the tetravalent metal cation and the oxide containing the pentavalent metal cation are mixed, by causing the high dielectric constant film to react with the oxide film; and forming an upper electrode.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart illustrating a method of manufacturing a semiconductor device according to a first embodiment.

FIGS. 2A to 2E are process cross-sectional views illustrating the method of manufacturing the semiconductor device according to the first embodiment.

FIG. 3 is a view illustrating a relationship between a CET and a leakage current in a ZrO₂ single film capacitor in the related art.

FIG. 4 is a cross-sectional view illustrating a portion of a capacitor structure in the related art.

FIG. 5 is a view illustrating a distribution of density of states (DOSs) obtained through calculation in a case where 5 sides among 16 sites of Ti in TiO₂ are replaced with Zr.

FIG. 6 is a view illustrating a relationship between a bandgap and the number of Zr atoms with which a site of Ti in TiO₂ is replaced.

FIG. 7 is a view illustrating a distribution of density of states (DOSs) obtained through calculation in cases where a replacement number of 24 sites of Nb in Nb₂O₅ with Zr is 0 and 8.

FIG. 8 is a view illustrating a relationship between a bandgap and the number of Zr atoms with which a site of Nb in Nb₂O₅ is replaced.

FIG. 9 is a view illustrating results obtained by actually manufacturing the semiconductor device (capacitor) of the first embodiment and detecting characteristics thereof.

FIG. 10 is a flowchart illustrating a method of manufacturing a semiconductor device according to a second embodiment.

FIGS. 11A to 11D are process cross-sectional views illustrating some processes of the method of manufacturing the semiconductor device according to the second embodiment.

FIG. 12 is a view illustrating a distribution of density of states (DOSs) obtained through calculation in a case where a displacement number of 28 sites of Nb in Nb₁₂O₂₉, which is oxygen-deficient with respect to Nb₂O₅, with Zr is 4.

FIG. 13 is a view illustrating a relationship between a bandgap and the number of Zr atoms with which a site of Nb in Nb₁₂O₂₉ is replaced as compared with a case where a site of Nb in Nb₂O₅ is replaced with Zr atoms.

FIG. 14 is a view illustrating a relationship between a bandgap and the number of Zr atoms with which a site of Ti in Ti₉O₁₇ is replaced as compared with a case where a site of Ti in TiO₂ is replaced with Zr atoms.

FIG. 15 is a view illustrating results obtained by actually manufacturing the semiconductor device (capacitor) of the second embodiment and detecting characteristics thereof.

FIG. 16 is a flowchart illustrating a method of manufacturing a semiconductor device according to a third embodiment.

FIGS. 17A to 17C are process cross-sectional views illustrating some processes of the method of manufacturing the semiconductor device according to the third embodiment.

FIG. 18 is a view illustrating results obtained by actually manufacturing the semiconductor device (capacitor) of the third embodiment and detecting characteristics thereof.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments will be described with reference to the accompanied drawings.

### First Embodiment

First, a first embodiment will be described.

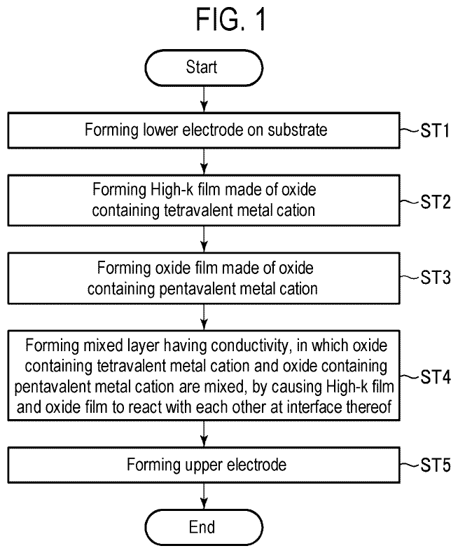

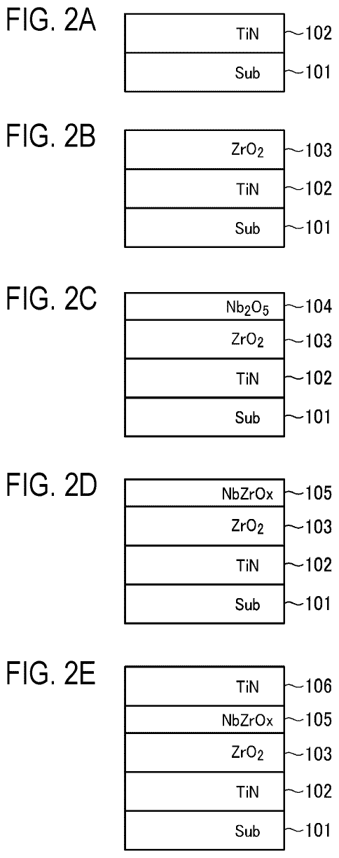

FIG. 1 is a flowchart illustrating a method of manufacturing of a semiconductor device according to a first embodiment, and FIGS. 2A to 2E are process cross-sectional views of the method.

In the present embodiment, first, a lower electrode 102 is formed on a substrate 101 (step ST1, FIG. 2A). The substrate 101 is not particularly limited, but a semiconductor substrate, e.g., a Si substrate is exemplified. The lower electrode 102 may be a TiN film. In addition to the TiN film, a TiSiN film, a TiAIN film, a TiMeN (Me: transition metal) film, a W film, a Mo film, and a Ru film may be used as the lower electrode 102. The lower electrode 102 may be formed by CVD, ALD or PVD (sputtering).

Subsequently, a high dielectric constant film (High-k film) 103 made of an oxide containing a tetravalent metal cation is formed as a capacitive film on the lower electrode 102 (step ST2, FIG. 2B). The High-k film 103 made of the oxide containing the tetravalent metal cation may be a ZrO₂ film or a HfO₂ film. The High-k film 103 may be formed by CVD, ALD or PVD (sputtering). A film thickness of the High-k film 103 may be within a range of 2 nm to 10 nm.

Subsequently, an oxide film 104 made of an oxide containing a pentavalent metal cation is formed on the High-k film 103 (step ST3, FIG. 2C). The oxide film 104 made of the oxide containing the pentavalent metal cation may be a Nb₂O₅ film, a Ta₂O₅ film, or a V₂O₅ film. The oxide film 104 may be formed by CVD, ALD or PVD (sputtering). A film thickness of the oxide film 104 may be 1 nm or less.

Subsequently, by causing the High-k film 103 to react with the oxide film 104 at an interface thereof, a mixed layer 105 having conductivity, in which the oxide containing the tetravalent metal cation and the oxide containing the pentavalent metal cation are mixed, is formed (step ST4, FIG. 2D). The mixed layer 105 may be formed as a reactive layer in annealing for crystallization of the High-k film 103. For example, when the High-k film 103 is the ZrO₂ film and the oxide film 104 is the Nb₂O₅ film, diffusion of Zr and Nb is generated by the annealing, and therefore, NbZrOₓ is formed as the mixed layer 105 having conductivity. The annealing temperature at this time may be within a range of 250 degrees C. to 600 degrees C. In addition, the annealing time may be 120 min or less. A composition of the mixed layer 105 may be adjusted according to temperature and time in the annealing, and the mixed layer 105 may become conductive by increasing an amount of Zr.

Subsequently, an upper electrode 106 is formed on the mixed layer 105 or the oxide film 104 (step ST5, FIG. 2E). The upper electrode 106 may be a TiN film. In addition to the TIN film, a TiSiN film, a TiAIN film, a TiMeN (Me: transition metal) film, a W film, a Mo film, and a Ru film may be used as the upper electrode 106. The upper electrode 106 may be formed by CVD, ALD or PVD (sputtering).

After the upper electrode 106 is formed, annealing for damage removal or the like is performed, and processing is ended. In addition, although the annealing is performed, it is difficult for a mixed layer by atom diffusion to be generated between the upper electrode 106 and the mixed layer 105.

In addition, in the present embodiment, the formation of the mixed layer 105 in the step ST4 may be performed after the formation of the upper electrode 106 in the step ST5.

The semiconductor device manufactured as described above is used as a capacitor, typically, a capacitor of a DRAM.

The semiconductor device manufactured by the method of the present embodiment includes, as illustrated in FIG. 2E, the lower electrode 102 formed on the substrate 101, the High-k film 103 made of the oxide containing the tetravalent metal cation, which is formed on the lower electrode 102, the mixed layer 105 formed on the High-k film 103, and the upper electrode 106 formed on the mixed layer 105.

In the present embodiment, since the mixed layer 105 is constituted by a combination of the tetravalent metal cation and the pentavalent metal cation, a defect for satisfying a charge neutrality condition is generated as will be described later, and therefore, the mixed layer 105 may become conductive. As the mixed layer 105 having conductivity is formed, a film thickness of a dielectric portion is thinned, and thus a capacity of the capacitor may be increased by decreasing a capacitance equivalent thickness (CET). Further, a leakage current may be reduced by existence of the mixed layer 105.

Hereinafter, this will be described in detail.

Recently, high integration and high speed of LSIs have progressed more and more, and design rules of semiconductor devices constituting the LSIs have been increasingly miniaturized. Accordingly, the capacity of a capacitor used for, for example, a DRAM tends to decrease, and hence an increase in capacity of the capacitor is required. As shown in Patent Document 1, in a capacitor in which a ZrO₂ film which is a High-k film as a dielectric film between TiN electrodes is provided as a single layer, the capacity of the capacitor may be increased by decreasing a CET through thinning of the ZrO₂ film. However, when the ZrO₂ film is thinned, an increase in leakage current is problematic, and therefore, it is difficult to promote the compatibility of high capacity by a decrease in CET and low leakage current. That is, as illustrated in FIG. 3, while the relationship between the CET and the leakage current is almost a linear relationship until the film thickness of the ZrO₂ film is about 3.5 nm, the leakage current may increase as compared with the line (trend line) when the film thickness of the ZrO₂ film becomes thinner than 3 nm and becomes, for example 2.5 nm. In addition, although Patent Document 2 describes a capacitor having a plurality of dielectric films, it is not intended even to promote the compatibility of high capacity and low leakage current.

Accordingly, in the present embodiment, the oxide film 104, e.g., Nb₂O₅, which is made of the oxide containing the pentavalent metal cation, is formed on the High-k film 103, e.g., the ZrO₂ film, which is made of the oxide containing the tetravalent metal cation. In addition, the annealing is performed to cause a reaction (atom diffusion) between the High-k film 103 and the oxide film 104 at the interface thereof, thereby forming the mixed layer 105 in which the High-k film 103 and the oxide film 104 are mixed. For example, when the High-k film 103 is the ZrO₂ film and the oxide film 104 is the Nb₂O₅, the mixed layer 105 containing NbZrOₓ is formed.

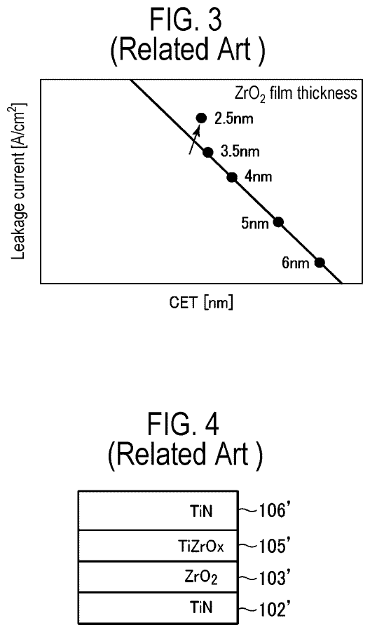

In the related art, for a capacitor provided with a ZrO₂ film 103′ as a dielectric film between a lower electrode 102′ and an upper electrode 106′, which are made of TiN shown in FIG. 4, a reaction (atom diffusion) is generated between the upper electrode 106′ and the ZrO₂ film 103′ by annealing after the upper electrode 106′ is formed, and therefore, a mixed layer (interface layer) 105′ made of TiZrOₓ is formed.

At this time, it may be considered that the mixed layer 105′ is obtained by replacing a portion of a site of Ti with Zr, and a defect structural formula in this case is shown in the following Equation 1.

$${ZrO}_{2} ( in {TiO}_{2} ) = {Zr}_{T i}^{x} + 2 {O}_{O}^{x} \qquad [ Equation 1 ]$$

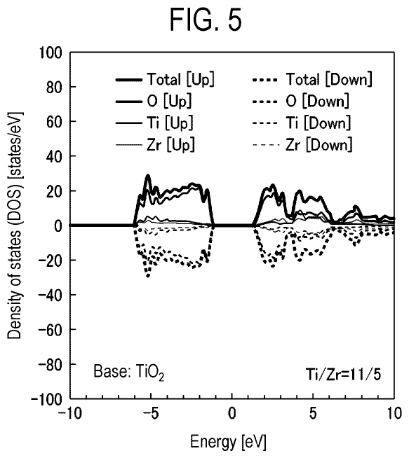

Since both the Ti and the Zr are tetravalent metal cations, and replacement of the site of Ti with Zr is replacement of the site of the tetravalent metal cation with the tetravalent metal cation, the charge neutrality condition may be maintained. Therefore, no electrical defect is formed. FIG. 5 is a view illustrating a distribution of density of states (DOSs) obtained through calculation in a case where 5 sites among 16 sites of Ti in TiO₂ are replaced with Zr. As illustrated in this drawing, it is possible to understand that a bandgap is formed in a DOS distribution, and the mixed layer 105′ made of the TiZrOₓ is insulative. In addition, “Up” and “Down” in the drawing are orientations of spin, and “Up” indicates that the DOS is positive, and “Down” indicates that the DOS is negative.

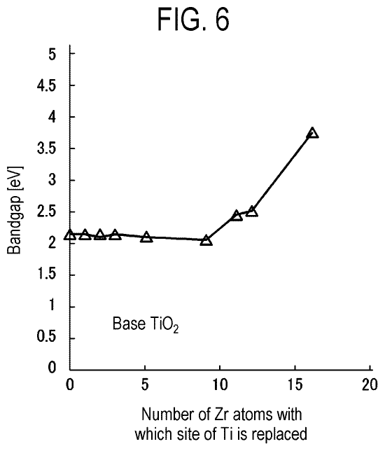

FIG. 6 is a view illustrating a relationship between a bandgap and the number of Zr atoms with which a site of Ti in TiO₂ is replaced. As shown in this drawing, it is possible to understand that the bandgap is not closed regardless of the replacement number of Zr atoms in the TiO₂, such that the TiO₂ acts as an insulator. Thus, the mixed layer 105′ is formed, such that the dielectric layer is film-increased as the mixed layer 105′ is formed.

That is, when the CET of the ZrO₂ film is CET_{ZrO2} and the CET of the TiZrOₓ which is the mixed layer 105′ is CET_{TiZrOx}, CET_{TZT} which is the CET of the entire capacitor becomes a sum of CET_{ZrO2} and CET_{TiZrOx} as described below, such that the mixed layer 105′ acts in a direction where the CET of the mixed layer 105′ increases.

$$C E {T}_{T Z T} = C E {T}_{TIZrOx} + {CET}_{ZrO 2}$$

In this regard, the mixed layer 105 of the present embodiment is obtained by mixing the oxide, e.g., the Nb₂O₅ containing the pentavalent metal cation with the oxide, e.g., the ZrO₂ containing the tetravalent metal cation, and the mixed layer 105 is, for example, NbZrOₓ. The defect structural formula when the ZrO₂ which is the oxide containing the tetravalent metal cation is added to the Nb₂O₅ which is the oxide containing the pentavalent metal cation, i.e., when a portion of a site of Nb is replaced with Zr is shown in the following Equation 2.

$$2 {ZrO}_{2} ( in {Nb}_{2} {O}_{5} ) = 2 {Zr}_{N b}^{′} + 5 {O}_{O}^{x} + {V}_{\ddot{O}} \qquad [ Equation 2 ]$$

When the site of the Nb which is a pentavalent metal cation is replaced with the Zr which is the tetravalent metal cation, in order to satisfy the charge neutrality condition, oxygen deficiency of the third term in the right hand side of Equation 2 and a defect caused by Zr charged with negative charges of the first term in the right hand side of Equation 2 are generated, such that the mixed layer 105 may become conductive.

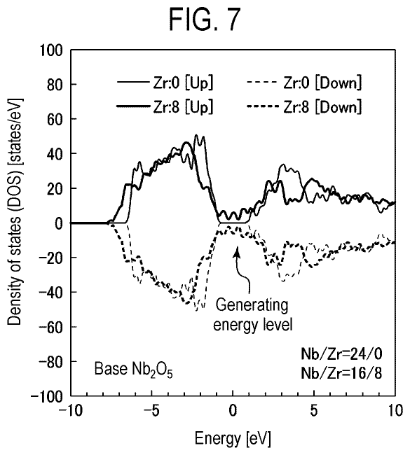

FIG. 7 is a view illustrating a distribution of density of states (DOSs) obtained through calculation in cases where a replacement number of 24 sites of Nb in Nb₂O₅ with Zr is 0 and 8. As illustrated in FIG. 7, it is confirmed that, through calculation, an energy level derived from an electron orbit of oxygen and Zr is generated in a gap of the DOS distribution when the replacement number with the Zr is 8, such that the mixed layer 105 become conductive.

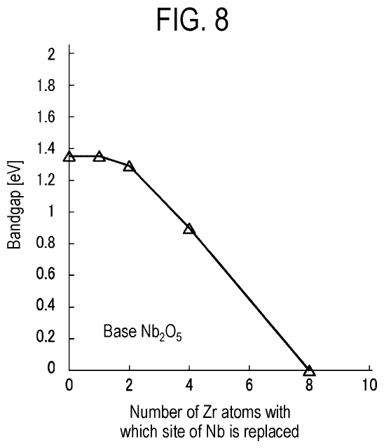

FIG. 8 is a view illustrating a relationship between a bandgap and the number of Zr atoms with which a site of Nb in Nb₂O₅ is replaced. As illustrated in this drawing, it is possible to understand that, when the replacement number of Zr atoms is 8 or more as the bandgap is narrowed along with an increase in the replacement number of Zr atoms in the Nb₂O₅, the bandgap is closed, such that the mixed layer 105 is changed to a conductor.

That is, in the present embodiment, the replacement number of the tetravalent metal cation (Zr in this example) in the mixed layer 105 is increased, such that the mixed layer 105 may become conductive. In the present embodiment, a thermal processing condition in annealing is adjusted, such that the mixed layer 105 having conductivity is formed.

When the CET of the ZrO₂ film is CET_{ZrO2} and the CET of the NbZrOₓ is CET_{NbZrOx} in a case where the High-k film 103 is the ZrO₂ film and the mixed layer 105 is the NbZrOₓ, the CET_{TNZT}, which is the CET of the entire capacitor, becomes a sum of the CET_{ZrO2} and the CET_{NbZrOx} as follows.

$$C E {T}_{T N Z T} = C E {T}_{N b ZrOx} + C E {T}_{Z r O 2}$$

Herein, since the NbZrOₓ is conductive, the CET_{NbZrOx} is almost 0. For this reason, a film thickness of a dielectric film is thinned as compared with a ZrO₂ single film capacitor in the related art, and thus the CET may be decreased. Further, by the existence of the NbZrOₓ which is the mixed layer 105, damage to the High-k film 103 in the formation of the upper electrode 106, or the like may be prevented. That is, when the mixed layer 105 does not exist, chemical damage by Cl, NH₃ or the like is given to the High-k film 103 in a case where the upper electrode 106 is formed by ALD, and physical damage by plasma is given to the High-k film 103 in a case where the upper electrode 106 is formed by PVD. Such damages are prevented by the existence of the mixed layer 105. For this reason, although the CET is small, the increase in leakage current may be suppressed. Therefore, a high capacity and a low leakage current of the capacitor are compatible.

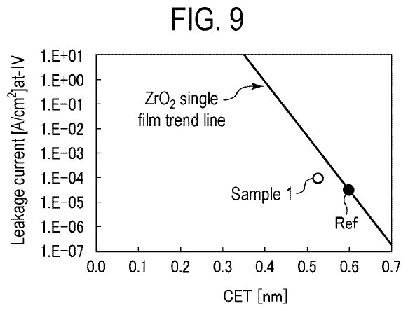

The semiconductor device (capacitor) of the present embodiment is actually manufactured, and characteristics thereof are detected. Herein, a capacitor is manufactured by forming a ZrO₂ film with a thickness of 4 nm and a Nb₂O₅ film with a thickness of 0.6 nm on a lower electrode made of a TiN film formed on a Si substrate, forming a NbZrOₓ film by performing annealing, and then forming an upper electrode made of a TiN film on the NbZrOₓ film (Sample 1). A CET and a leakage current are obtained with respect to the capacitor of this Sample 1. As a result, as illustrated in FIG. 9, it is confirmed that the CET may be decreased by 15% while suppressing an increase in leakage current as compared with a capacitor (Ref) of a structure in the related art, in which a single film ZrO₂ is used, and thus characteristics are improved as compared with a trend line of the single film ZrO₂.

### Second Embodiment

Next, a second embodiment will be described.

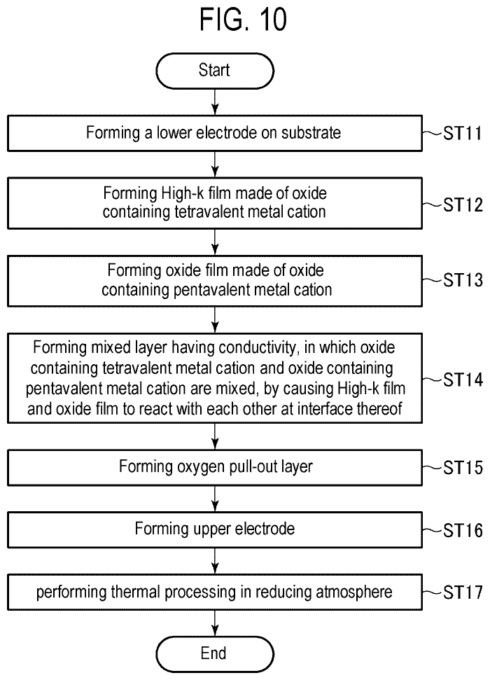

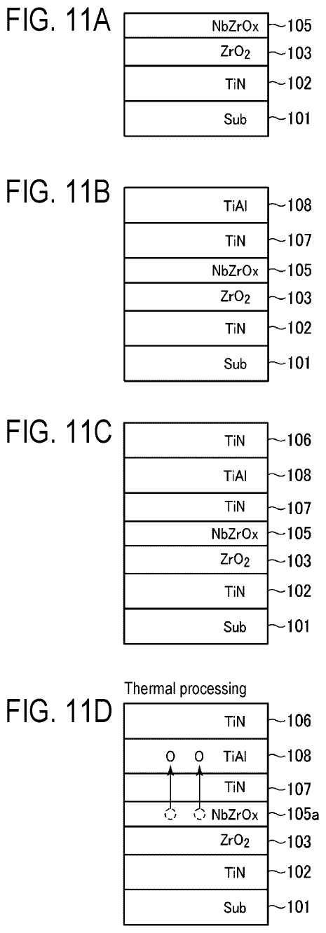

FIG. 10 is a flowchart illustrating a method of manufacturing a semiconductor device according to a second embodiment, and FIGS. 11A to 11D are process cross-sectional views illustrating some processes of the method of the second embodiment.

In the present embodiment, steps ST11 to ST13 similar to the steps ST1 to ST3 of the first embodiment are performed. That is, a lower electrode 102 is formed on a substrate 101 (step ST11), a high dielectric constant film (High-k film) 103 made of an oxide containing a tetravalent metal cation is formed as a capacitive film (step ST12), and an oxide film 104 made of an oxide containing a pentavalent metal cation is formed on the High-k film 103 (step ST13).

Subsequently, like the step ST4 of the first embodiment, by causing the High-k film 103 to react with the oxide film 104 at an interface thereof, for example, in annealing for crystallization of the High-k film 103, a mixed layer 105 having conductivity, in which the oxide containing the tetravalent metal cation and the oxide containing the pentavalent metal cation are mixed, is formed (step ST14, FIG. 11A).

Subsequently, an oxygen pull-out layer 108 to pull out oxygen is formed on the mixed layer 105 (step ST15, FIG. 11B). At this time, as illustrated in FIG. 11B, the oxygen pull-out layer 108 is formed by interposing a barrier film 107 made of, for example, a TiN film between the mixed layer 105 and the oxygen pull-out layer 108. As the oxygen pull-out layer 108, a metal layer made of an active metal such as TiAl may be used. In addition to the TiAl, Ti, Al, and the like may be used for the oxygen pull-out layer 108.

Subsequently, like the step ST5 of the first embodiment, an upper electrode 106 made of, for example, a TiN film is formed on the oxygen pull-out layer 108 (step ST16, FIG. 11C).

Subsequently, a thermal processing is performed in a reducing atmosphere (step ST17, FIG. 11D). As a result, oxygen is pulled out into the oxygen pull-out layer 108 from the lower mixed layer 105, such that a mixed layer 105a in which oxygen deficiency is generated is formed. The thermal processing at this time may be performed under a condition of H₂-containing atmosphere (hydrogen concentration: 1% to 100%, e.g., 4%), temperature: 350 degrees C. to 600 degrees C., e.g., 400 degrees C., and time: 120 min or less, e.g., 10 min.

The formation of the oxygen pull-out layer 108 in the step ST15 and the thermal processing in the reducing atmosphere in the step ST17 constitute a reduction processing process.

After the step ST17, annealing is further performed as required, and the process is ended.

In addition, in the present embodiment, the formation of the mixed layer 105 in the step ST14 may be performed in the step ST17 and be performed in the annealing after the step ST17. In a case where the step ST14 is performed in the annealing after the step ST17, the pulling-out (reduction processing) of oxygen in the step ST17 is performed on the oxide film 104.

In the present embodiment, the semiconductor device manufactured as described above is also used as a capacitor, typically, a capacitor of a DRAM.

In the present embodiment, oxygen deficiency is generated by performing pulling-out of oxygen, which is a reduction processing, on the mixed layer 105 constituted by a combination of the tetravalent metal cation and the pentavalent metal cation, in which a defect for satisfying the charge neutrality condition is generated, such that the mixed layer 105a in which the oxygen deficiency is generated is formed. For this reason, the mixed layer 105a easily becomes conductive by the existence of oxygen deficiency as compared with the mixed layer 105, such that conductivity may be increased. Thus, an effect of decreasing the CET may be enhanced as compared with the first embodiment. Further, in addition to damage to the High-k film 103 in the formation of the upper electrode 106 as described above, damage to the High-k film 103 in the reduction processing may be prevented by the existence of the mixed layer 105a, and thus an increase in leakage current may be suppressed.

Hereinafter, this will be described in detail.

As described above, oxygen deficiency and a defect caused by Zr charged with negative charges are generated in the mixed layer 105 in which the oxide, e.g., Nb₂O₅ containing the pentavalent metal cation and the oxide, e.g., ZrO₂ containing the tetravalent metal cation are mixed, such that the mixed layer 105 may become conductive. Further, oxygen is pulled out from the mixed layer 105, such that it is easier for the mixed layer 105a in which the oxygen deficiency increases to become conductive.

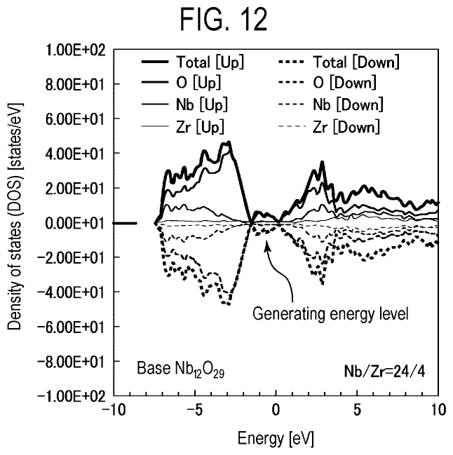

FIG. 12 is a view illustrating a distribution of density of states (DOSs) obtained through calculation in a case where a displacement number of 28 sites of Nb in Nb₁₂O₂₉, which is oxygen-deficient with respect to Nb₂O₅, with Zr is 4. As illustrated in FIG. 12, it is confirmed that, in the case of the Nb₁₂O₂₉ which is oxygen-deficient with respect to the Nb₂O₅, at least an energy level derived from an electron orbit of oxygen and Zr is generated in a gap of the DOS distribution when the replacement number with the Zr is 4, such that the mixed layer 105 becomes conductive.

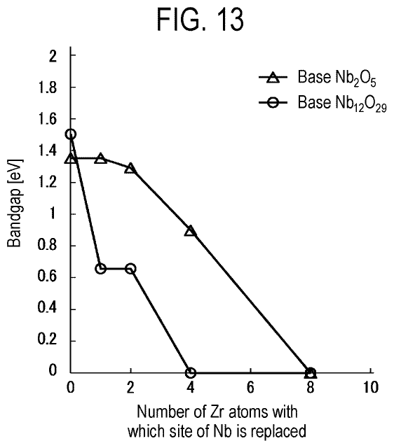

FIG. 13 is a view illustrating a relationship between a bandgap and the number of Zr atoms with which a site of Nb in Nb₁₂O₂₉ is replaced as compared with a case where a site of Nb in Nb₂O₅ is replaced with Zr atoms. As illustrated in this drawing, it is possible to know that, in the case of the Nb₁₂O₂₉ which is oxygen-deficient with respect to the Nb₂O₅, the bandgap is rapidly narrowed by the replacement with the Zr atoms as compared with the case of the Nb₂O₅, and is closed when the replacement number with the Zr atoms is 4 or more, such that the mixed layer 105 is changed to a conductor.

That is, in the present embodiment, the mixed layer 105a in which the oxygen deficiency is increased by performing the pulling-out of oxygen, which is the reduction processing, on the mixed layer 105 easily becomes conductive as compared with the mixed layer 105. For this reason, the CET may be further decreased as compared with the first embodiment.

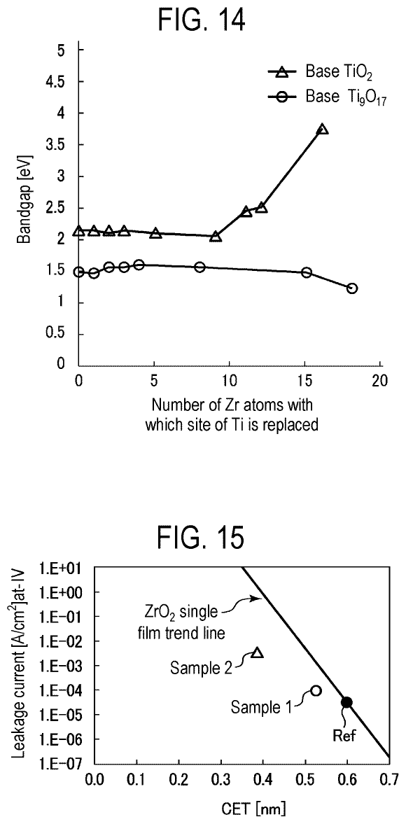

In addition, in the case of the capacitor in the related art where the oxide film 104 made of the oxide containing the pentavalent metal cation is not formed as illustrated in FIG. 4, although the mixed layer (interface layer) 105′ is formed and then oxygen deficiency is generated by reduction processing, the mixed layer (interface layer) 105′ is an insulator as it is. This will be described with reference to FIG. 14. FIG. 14 is a view illustrating a relationship between a bandgap and the number of Zr atoms with which a site of Ti in Ti₉O₁₇ is replaced as compared with a case where a site of Ti in TiO₂ is replaced with Zr atoms. From this drawing, it is possible to understand that, the bandgap is not closed regardless of the replacement number of Zr atoms in the Ti₉O₁₇ which generates oxygen deficiency like the TiO₂, such that the Ti₉O₁₇ acts as an insulator.

The semiconductor device (capacitor) of the present embodiment is actually manufactured, and characteristics thereof are detected. Herein, a ZrO₂ film with a thickness of 4 nm and a Nb₂O₅ film with a thickness of 0.6 nm are formed on a lower electrode made of a TiN film formed on a Si substrate, and then a NbZrOₓ film is formed by performing annealing. In addition, a TiN film with a thickness of 3 nm and a TiAl film with a thickness of 3 nm are formed on the NbZrOₓ film, an upper electrode made of a TiN film was formed, and then a thermal process of 400 degrees C. is performed in a reducing atmosphere, thereby manufacturing a capacitor (Sample 2). A CET and a leakage current are obtained with respect to the capacitor of this Sample 2. As a result, as illustrated in FIG. 15, it is confirmed the CET may be decreased by 35% while suppressing an increase in leakage current to two digits or less as compared with a capacitor (Ref) of a structure in the related art, which uses a single film ZrO₂, and thus characteristics thereof are improved as compared with a trend line of the single film ZrO₂. Further, in FIG. 15, it is possible to understand that, the results of the Sample 1 of the first embodiment are also written, a CET decreasing effect of the Sample 2 is higher than that of the Sample 1.

### Third Embodiment

Next, a third embodiment will be described.

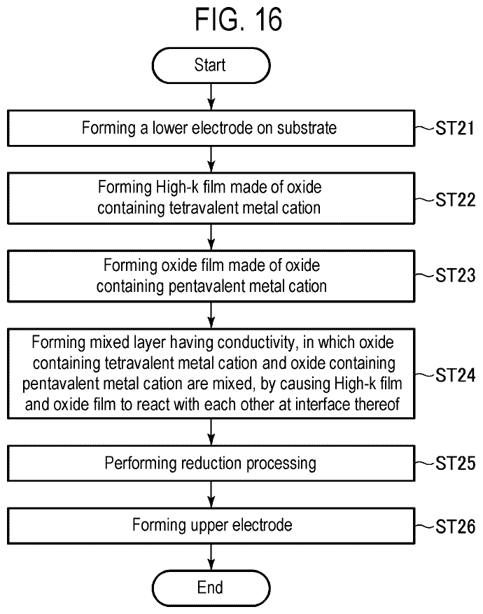

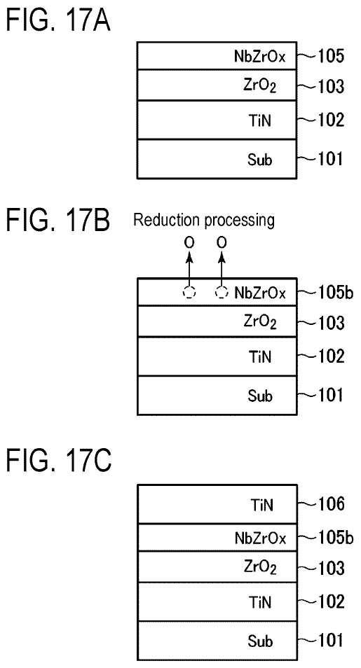

FIG. 16 is a flowchart illustrating a method of manufacturing a semiconductor device according to a third embodiment, and FIGS. 17A to 17C are process cross-sectional views illustrating some processes of the method of the third embodiment.

In the present embodiment, steps ST21 to ST23 similar to the steps ST1 to ST3 of the first embodiment are performed. That is, a lower electrode 102 is formed on a substrate 101 (step ST21), a high dielectric constant film (High-k film) 103 made of an oxide containing a tetravalent metal cation is formed as a capacitive film (step ST22), and an oxide film 104 made of an oxide containing a pentavalent metal cation is formed on the High-k film 103 (step ST23).

Subsequently, like the step ST4 of the first embodiment, by causing the High-k film 103 to react with the oxide film 104 at an interface thereof, for example, in annealing for crystallization of the High-k film 103, a mixed layer 105 having conductivity, in which the oxide containing the tetravalent metal cation and the oxide containing the pentavalent metal cation are mixed, is formed (step ST24, FIG. 17A).

Subsequently, a reduction processing is performed (step ST25, FIG. 17B). Accordingly, a mixed layer 105b in which oxygen deficiency is generated as the mixed layer 105 is reduced is formed. The reduction processing may be performed by a thermal processing in a hydrogen gas (H₂ gas) atmosphere or a deuterium gas (D₂ gas) atmosphere as a reducing atmosphere, and be performed, for example, under a condition of temperature: 250 degrees C. to 600 degrees C. and time: 60 min or less. Further, the reduction processing may be performed by using H₂ plasma.

Subsequently, like the step ST5 of the first embodiment, an upper electrode 106 made of, for example, a TiN film is formed on the mixed layer 105b (step ST26, FIG. 17C).

After the step ST26, annealing is performed as required, and the process is ended.

In addition, in the present embodiment, the formation of the mixed layer 105 in the step ST24 may be performed in the step ST26 and be performed in the annealing after the step ST26. In a case where the step ST24 is performed in the annealing after the step ST26, oxygen deficiency is generated in the oxide film 104 in the reduction processing in the step ST25.

In the present embodiment, the semiconductor device manufactured as described above is also used as a capacitor, typically, a capacitor of a DRAM.

In the present embodiment, like the second embodiment, the mixed layer 105b in which the oxygen deficiency is generated with respect to the mixed layer 105 is formed by performing the reduction processing on the mixed layer 105 constituted by a combination of the tetravalent metal cation and the pentavalent metal cation, in which a defect for satisfying a charge neutrality condition is generated. For this reason, the mixed layer 105b easily becomes conductive by the existence of oxygen deficiency as compared with the mixed layer 105, such that conductivity may be increased. Thus, the effect of decreasing the CET may be enhanced as compared with the first embodiment. Further, like the mixed layer 105a of the second embodiment, damage to the High-k film 103 in the reduction processing in addition to in the formation of the upper electrode 106 may be prevented by the mixed layer 105b, and an increase in leakage current may be suppressed.

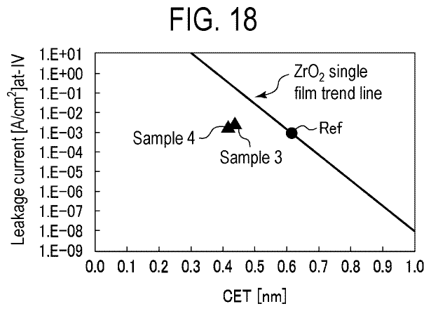

The semiconductor device (capacitor) of the present embodiment is actually manufactured, and characteristics thereof are detected. Herein, a ZrO₂ film with a thickness of 4 nm and a Nb₂O₅ film with a thickness of 0.6 nm are formed on a lower electrode made of a TiN film formed on a Si substrate, and then a NbZrOₓ film is formed by performing annealing. In addition, a reduction processing of 541 degrees C. is performed in a H₂ gas atmosphere, and an upper electrode made of a TiN film is formed on the NbZrOₓ film, thereby manufacturing a capacitor (Sample 3). A capacitor is manufactured in a condition similar to that of the Sample 3 except that the reduction process is performed in a D₂ gas atmosphere (Sample 4). A CET and a leakage current are obtained with respect to each of these capacitors. As a result, as illustrated in FIG. 18, it is confirmed the CET may be decreased by 30% while suppressing an increase in leakage current to two digits or less as compared with a capacitor (Ref) of a structure in the related art, which uses a single film ZrO₂, and thus characteristics thereof are improved as compared with a trend line of the single film ZrO₂.

### <Other Applications>

In the above, the embodiments have been described, but it should be understood that the embodiments disclosed herein are illustrative in all respects and are not restrictive. The embodiments described above may be omitted, replaced, and changed in various ways without departing from the accompanying claims and the subject thereof.

According to the present disclosure in some embodiments, it is possible to provide a method of manufacturing a semiconductor device and a semiconductor device, in which a high capacity and a low leakage current of a capacitor are compatible.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of manufacturing a semiconductor device, the method comprising:
forming a lower electrode on a substrate;
forming, on the lower electrode, a high dielectric constant film made of an oxide containing a tetravalent metal cation;
forming, on the high dielectric constant film, an oxide film made of an oxide containing a pentavalent metal cation;
forming a mixed layer having conductivity, in which the oxide containing the tetravalent metal cation and the oxide containing the pentavalent metal cation are mixed, by causing the high dielectric constant film to react with the oxide film; and
forming an upper electrode.

2. The method of claim 1, wherein the high dielectric constant film made of the oxide containing the tetravalent metal cation is any one of a ZrO₂ film and a HfO₂ film.

3. The method of claim 1, wherein the oxide film made of the oxide containing the pentavalent metal cation is any one of a Nb₂O₅ film, a V₂O₅ film, and a Ta₂O₅ film.

4. The method of claim 1, wherein the high dielectric constant film made of the oxide containing the tetravalent metal cation is a ZrO₂ film, and the oxide film made of the oxide containing the pentavalent metal cation is a Nb₂O₅ film.

5. The method of claim 1, wherein the upper electrode and the lower electrode are made of a TiN film.

6. The method of claim 1, further comprising performing a reduction processing at least after the forming the oxide film.

7. The method of claim 6, wherein, in the performing the reduction processing, an oxygen pull-out layer is formed on the mixed layer or the oxide film, and then oxygen is pulled out into the oxygen pull-out layer from the mixed layer or the oxide film by a thermal processing in a reducing atmosphere.

8. The method of claim 7, wherein the thermal processing in the reducing atmosphere is performed after the forming the upper electrode.

9. The method of claim 7, wherein oxygen deficiency is generated in the mixed layer by pulling out oxygen into the oxygen pull-out layer.

10. The method of claim 6, wherein, in the performing the reduction processing, the reduction processing is performed by a thermal processing in a hydrogen gas atmosphere or a deuterium gas atmosphere.

11. The method of claim 10, wherein oxygen deficiency is generated in the mixed layer by the thermal processing in the hydrogen gas atmosphere or the deuterium gas atmosphere.

12. The method of claim 10, wherein, in the performing the reduction processing, the reduction processing is performed before the forming the upper electrode.

13. The method of claim 1, wherein a film thickness of the oxide film is 1 nm or less.

14. The method of claim 1, wherein the semiconductor device is a capacitor of a DRAM.

15. A semiconductor device comprising:
a substrate;
a lower electrode formed on the substrate;
a high dielectric constant film made of an oxide containing a tetravalent metal cation, and formed on the lower electrode;
a mixed layer formed on the high dielectric constant film, the mixed layer having conductivity, in which the oxide containing the tetravalent metal cation and an oxide containing a pentavalent metal cation are mixed; and
an upper electrode formed on the mixed layer.

16. The semiconductor device of claim 15, wherein the mixed layer has oxygen deficiency.

17. The semiconductor device of claim 15, wherein the semiconductor device is used as a capacitor of a DRAM.
